(19) United States
(12) Patent Application Publication
(10) Pub. No.: US 2025/0301791 A1
(43) Pub. Date: Sep. 25, 2025

(54) SEMICONDUCTOR DEVICE WITH DIELECTRIC THERMAL CONDUCTOR

(71) Applicant: INTERNATIONAL BUSINESS MACHINES CORPORATION, ARMONK, NY (US)

(72) Inventors: Debarghya Sarkar, Latham, NY (US); Ruilong Xie, Niskayuna, NY (US); Prabudhya Roy Chowdhury, Albany, NY (US); Abir Shadman, Albany, NY (US); Kisik Choi, Watervliet, NY (US)

(21) Appl. No.: 18/610,973

(22) Filed: Mar. 20, 2024

(51) Int. Cl. H01L 27/12; H01L 23/373

(52) U.S. Cl. CPC H10D 86/60; H10D 86/0214; H10D 86/441; H10D 86/451; H01L 23/3731

(57) ABSTRACT

A semiconductor device is provided. The semiconductor device includes a backside power distribution (BSPDN), a high thermal conductivity dielectric layer, a heat sink, and a heat transfer pillar. The heat transfer pillar is connected to the high thermal conductivity dielectric layer and extends to the heat sink.

### FIELD OF THE INVENTION

The present disclosure relates to fabrication methods and resulting structures for semiconductor devices. More specifically, the present disclosure relates to fabrication methods and resulting semiconductor devices with backside power distribution networks and heat dissipation structures.

### BACKGROUND

In general, a power delivery network for a semiconductor device is designed to provide a power supply and a reference voltage to the active devices on the chip. Traditionally, a power delivery network may include a network of metal wires fabricated through back-end-of-line (BEOL) processing on a frontside of the wafer. The power delivery network shares this space with the interconnects that are designed to transport the signals. A semiconductor device may include a front-end-of-line (FEOL) region, a middle-of-line (MOL) region, and a BEOL region. In general, the FEOL is the first portion of integrated circuit (IC) fabrication where the individual components (e.g., transistors, capacitors, resistors, etc.) are patterned in the semiconductor. FEOL generally covers everything up to (but not including) the deposition of metal interconnect layers. The back end of line (BEOL) region is the second portion of IC fabrication where the individual devices (transistors, capacitors, resistors, etc.) get interconnected with wiring on the wafer. In general, the MOL refers to the set of wafer processing steps used to create the structures that provide the local electrical connections between transistors (mainly gate contact formation), and these processing steps occur after the FEOL (transistors) and before the BEOL (wiring) processes. BEOL processing generally begins when the first layer of metal is deposited on the wafer. BEOL includes contacts, insulating layers (dielectrics), metal levels, and bonding sites for chip-to-package connections.

The layers in the FEOL region include transistors, which generate a significant amount of heat. In order to maintain a proper working temperature for these various transistors, it is desirable to effectively transfer the generated heat away from these devices to, for example, a cooling module.

### SUMMARY

Embodiments of the present disclosure relate to a semiconductor device. The semiconductor device includes a backside power distribution (BSPDN), a high thermal conductivity dielectric layer, a heat sink, and a heat transfer pillar. The heat transfer pillar is connected to the high thermal conductivity dielectric layer and extends to the heat sink.

Embodiments of the present disclosure relate to an electronic device. The electronic device includes a semiconductor device. The semiconductor device includes a backside power distribution (BSPDN), a high thermal conductivity dielectric layer, a heat sink, and a heat transfer pillar. The heat transfer pillar is connected to the high thermal conductivity dielectric layer and extends to the heat sink.

Embodiments of the present disclosure relate to a semiconductor device. The semiconductor device includes a backside power distribution (BSPDN), a front end of line (FEOL) region on the BSPDN, a middle of line/back end of line (MOL/BEOL) region on the FEOL, a heat sink on the MOL/BEOL region, a high thermal conductivity dielectric layer, a heat transfer pillar. The heat transfer pillar is connected to the high thermal conductivity dielectric layer and extends to the heat sink.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a cross-sectional view of a semiconductor device at an intermediate stage of the fabrication process, taken along the line X1-X2 of FIG. 1B, according to embodiments.

FIG. 1B is simplified top-down view of the semiconductor device of FIG. 1A, according to embodiments.

FIG. 1C is a cross-sectional view of the semiconductor device of FIG. 1A, taken along the line Y1-Y2 of FIG. 1B, according to embodiments.

FIG. 2A is a cross-sectional view of the semiconductor device of FIG. 1A after additional fabrication operations, taken along the line X1-X2 of FIG. 1B, according to embodiments.

FIG. 2B is a cross-sectional view of the semiconductor device of FIG. 1C after additional fabrication operations, taken along the line Y1-Y2 of FIG. 1B, according to embodiments.

FIG. 3A is a cross-sectional view of the semiconductor device of FIG. 2A after additional fabrication operations, taken along the line X1-X2 of FIG. 1B, according to embodiments.

FIG. 3B is a cross-sectional view of the semiconductor device of FIG. 2B after additional fabrication operations, taken along the line Y1-Y2 of FIG. 1B, according to embodiments.

FIG. 4A is a cross-sectional view of the semiconductor device of FIG. 3A after embodiments.

FIG. 4B is a cross-sectional view of the semiconductor device of FIG. 3B after additional fabrication operations, taken along the line Y1-Y2 of FIG. 1B, according to embodiments.

FIG. 5A is a cross-sectional view of the semiconductor device of FIG. 4A after additional fabrication operations, taken along the line X1-X2 of FIG. 1B, according to embodiments.

FIG. 5B is a cross-sectional view of the semiconductor device of FIG. 4B after additional fabrication operations, taken along the line Y1-Y2 of FIG. 1B, according to embodiments.

FIG. 6A is a cross-sectional view of the semiconductor device of FIG. 5A after additional fabrication operations, taken along the line X1-X2 of FIG. 1B, according to embodiments.

FIG. 6B is a cross-sectional view of the semiconductor device of FIG. 5B after additional fabrication operations, taken along the line Y1-Y2 of FIG. 1B, according to embodiments.

FIG. 7A is a cross-sectional view of the semiconductor device of FIG. 6A after additional fabrication operations, taken along the line X1-X2 of FIG. 1B, according to embodiments.

FIG. 7B is a cross-sectional view of the semiconductor device of FIG. 6B after additional fabrication operations, taken along the line Y1-Y2 of FIG. 1B, according to embodiments.

FIG. 8A is a cross-sectional view of the semiconductor device of FIG. 7A after embodiments.

FIG. 8B is a cross-sectional view of the semiconductor device of FIG. 7B after additional fabrication operations, taken along the line Y1-Y2 of FIG. 1B, according to embodiments.

FIG. 9A is a cross-sectional view of the semiconductor device of FIG. 8A after additional fabrication operations, taken along the line X1-X2 of FIG. 1B, according to embodiments.

FIG. 9B is a cross-sectional view of the semiconductor device of FIG. 8B after additional fabrication operations, taken along the line Y1-Y2 of FIG. 1B, according to embodiments.

FIG. 10A is a cross-sectional view of the semiconductor device of FIG. 9A after additional fabrication operations, taken along the line X1-X2 of FIG. 1B, according to embodiments.

FIG. 10B is a cross-sectional view of the semiconductor device of FIG. 9B after additional fabrication operations, taken along the line Y1-Y2 of FIG. 1B, according to embodiments.

FIG. 11A is a cross-sectional view of the semiconductor device of FIG. 10A after additional fabrication operations, taken along the line X1-X2 of FIG. 1B, according to embodiments.

FIG. 11B is a cross-sectional view of the semiconductor device of FIG. 10B after additional fabrication operations, taken along the line Y1-Y2 of FIG. 1B, according to embodiments.

FIG. 12A is a cross-sectional view of the semiconductor device of FIG. 11A after embodiments.

FIG. 12B is a cross-sectional view of the semiconductor device of FIG. 11B after additional fabrication operations, taken along the line Y1-Y2 of FIG. 1B, according to embodiments.

FIG. 13A is a cross-sectional view of a semiconductor device, taken along the line X1-X2 of FIG. 1B where the high thermal conductivity dielectric layer is formed as a planar layer on an interlayer dielectric layer, according to embodiments.

FIG. 13B is a cross-sectional view of the semiconductor device of FIG. 13A, taken along the line Y1-Y2 of FIG. 1B, according to embodiments.

FIG. 14A is a cross-sectional view of a semiconductor device, taken along the line X1-X2 of FIG. 1B where the high thermal conductivity dielectric layer is formed as a planar layer on a bottom interlayer dielectric layer, according to embodiments.

FIG. 14B is a cross-sectional view of the semiconductor device of FIG. 14A, taken along the line Y1-Y2 of FIG. 1B, according to embodiments.

FIG. 15A is a cross-sectional view of a semiconductor device showing the high thermal conductivity dielectric layer that contacts a vertical heat transfer pillar, according to embodiments.

FIG. 15B is a cross-sectional view of a semiconductor device showing the high thermal conductivity dielectric layer that contacts a vertical heat transfer pillar, according to embodiments.

FIG. 15C is a cross-sectional view of a semiconductor device showing the high thermal conductivity dielectric layer that contacts a vertical heat transfer pillar, according to embodiments.

FIG. 15D is a cross-sectional view of a semiconductor device showing the high thermal conductivity dielectric layer that contacts a vertical heat transfer pillar, according to embodiments.

FIG. 15E is a cross-sectional view of a semiconductor device showing the high thermal conductivity dielectric layer that contacts a vertical heat transfer pillar, according to embodiments.

### DETAILED DESCRIPTION

The flowcharts and cross-sectional diagrams in the Figures illustrate methods of manufacturing semiconductor devices according to various embodiments. In some alternative implementations, the manufacturing steps may occur in a different order than that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA structure, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides improved channel electrostatics control, which may be helpful for continuously scaling gate lengths down to seven (7) nanometer CMOS technology and below.

In certain semiconductor devices, a frontside power distribution network (FSPDN) may be utilized, and this is formed on the frontside of the semiconductor wafer. In other examples, a backside power distribution network (BSPDN) may be utilized. In general, a BSPDN allows for the decoupling of the power delivery network from the signal network by moving the entire power distribution network to the backside of the silicon wafer rather than the frontside (i.e., as in a FSPDN). However, the BSPDN may have an increased thermal resistance (e.g., about 15%) relative to a FSPDN, which may make it more difficult to transfer heat out of the device. Accordingly, it may be desirable to improve the effectiveness and efficiency of heat transfer out of a semiconductor device that utilizes a BSPDN.

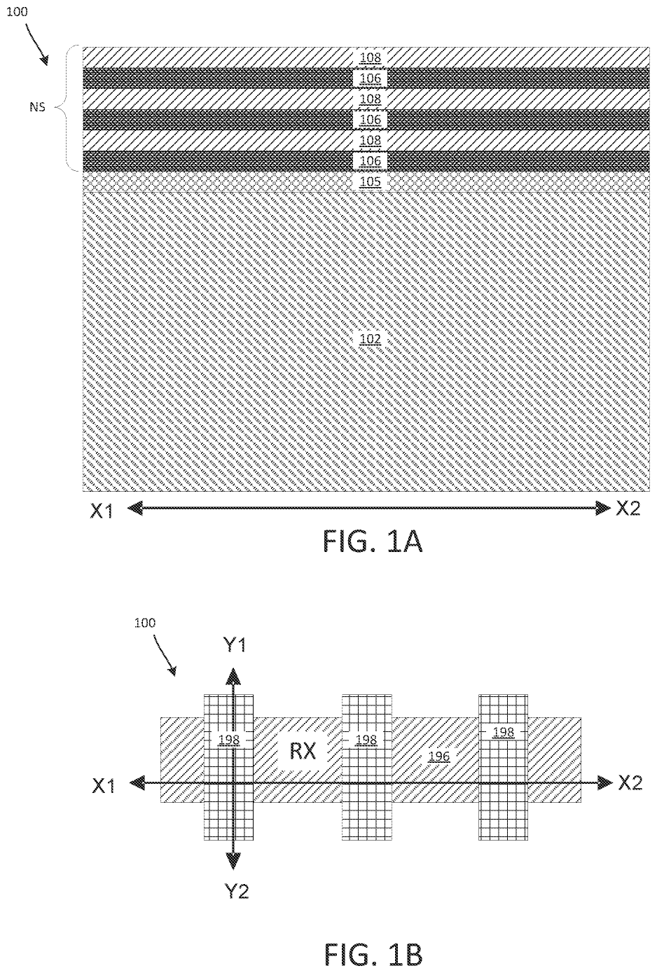

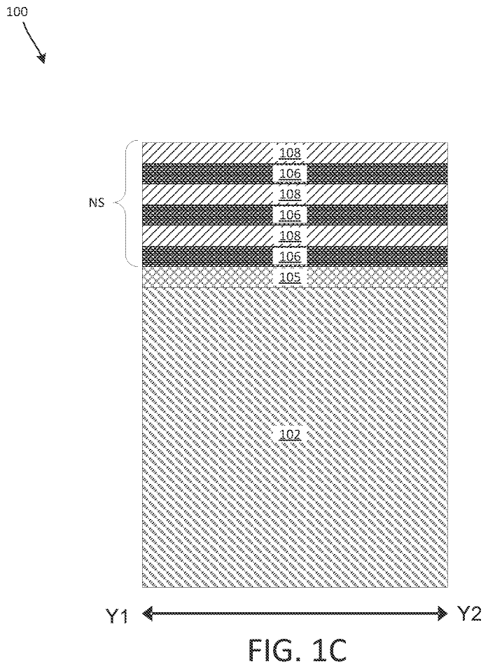

Referring now to the drawings in which like numerals represent the same or similar elements and initially to FIGS. 1A, 1B, and 1C, FIG. 1A is a cross-sectional view of the semiconductor device 100 at an intermediate stage of the fabrication process taken along the line X1-X2 of FIG. 1B, FIG. 1B is simplified top-down view of the semiconductor device 100 of FIG. 1A, and FIG. 1C is a cross-sectional view of the semiconductor device 100 of FIG. 1A taken along the line Y1-Y2 of FIG. 1B. As shown in FIGS. 1A and 1C, a semiconductor device 100 including a nanosheet stack NS is shown at an intermediate stage of the manufacturing process, according to embodiments. The simplified top-down view of FIG. 1B shows a general layout of the active region 196 of the semiconductor device 100 and the channel regions 198.

As shown in FIGS. 1A and 1C, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. The substrate 102 may be comprised of any other suitable material(s) than those listed above.

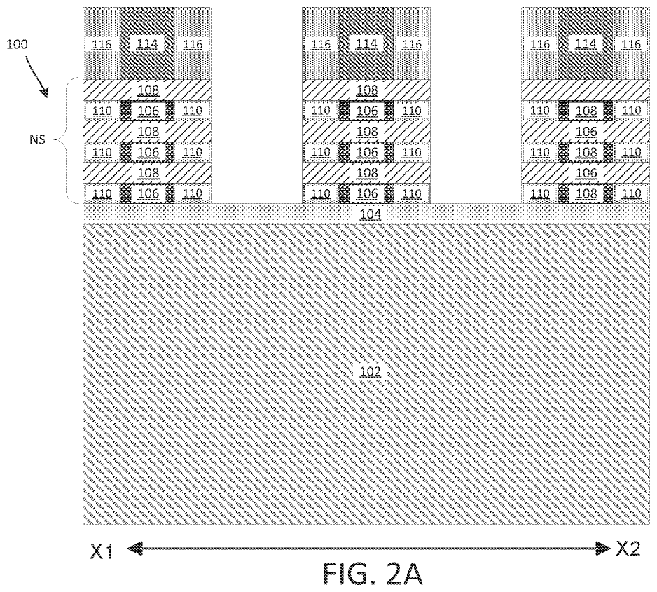

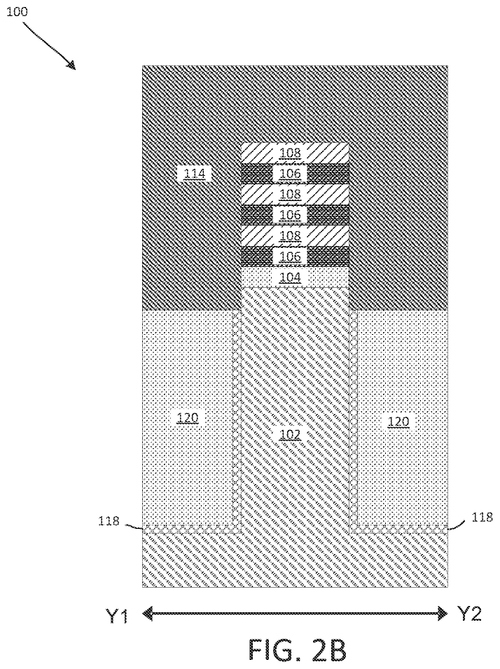

As shown in FIGS. 1A and 1C, a temporary sacrificial layer 105 is formed on the substrate 102. This temporary sacrificial layer 105 will be later removed and replaced with a bottom dielectric isolation (BDI) layer 104 shown in FIGS. 2A-2B. The nanosheet stack NS includes alternating layers of a sacrificial layer 106 and a semiconductor layer 108. The bottom nanosheet stack NS initially includes a sacrificial layer 106 that is formed on the BDI layer 104, followed by the formation of a semiconductor layer 108. In an example, the sacrificial layer 106 is composed of silicon-germanium (e.g., SiGe, or more generally, where the Ge ranges from about 15-35%). Further, the first (or bottommost) semiconductor layer 108 is formed on an upper surface of the first one of the sacrificial layers 106. In the example illustrated in FIGS. 1A and 1C, there are a total of three sacrificial layers 106 and three active semiconductor layers 108 that are alternately formed to form the nanosheet stack 103. However, it should be appreciated that any suitable number of alternating layers may be formed. Although it is specifically contemplated that the sacrificial layers 106 can be formed from silicon germanium and that the active semiconductor layers 108 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials can be deposited by any appropriate mechanism. It is specifically contemplated that the first and second semiconductor materials (i.e., of the sacrificial layers 106 and the active semiconductor layers 108) can be epitaxially grown from one another, but alternate deposition processes, such as CVD, PVD, ALD, or gas cluster ion beam (GCIB) deposition, are also contemplated.

In certain embodiments, the sacrificial layers 106 have a vertical thickness ranging, for example, from approximately 3 nm to approximately 20 nm. In certain embodiments, the semiconductor layers 108 have a vertical thickness ranging, for example, from approximately 3 nanometers (nm) to approximately 10 nm. Although the range of 3-20 nm is cited as an example range of thickness, other thicknesses of these layers may be used. In certain examples, certain of the sacrificial layers 106 and/or the semiconductor layers 108 may have different thicknesses relative to one another. Therefore, multiple epitaxial growth processes can be performed to form the sacrificial layers 106 and the semiconductor layers 108.

In certain embodiments, it may be desirable to have a small vertical spacing (VSP) between adjacent nanosheet layers in the nanosheet stack NS to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 106.

Referring now to FIGS. 2A and 2B, FIG. 2A is a cross-sectional view of the semiconductor device 100 of FIG. 1A at a subsequent stage of the fabrication process, taken along the line X1-X2 of FIG. 1B, and FIG. 2B is a cross-sectional view of the semiconductor device 100 of FIG. 1C at a subsequent stage of the fabrication process, taken along the line Y1-Y2 of FIG. 1B. As shown in FIGS. 2A and 2B, the temporary sacrificial layer 105 is removed by any suitable material removal process, and is replaced with the bottom dielectric isolation layer 104. The bottom dielectric isolation layer 104 may comprise one or more insulating materials such as a low-k material, silicon nitride (SiN), silicon boron carbonitride (SiBCN), silicon oxycarbonitride (SiOCN), silicon oxynitride (SiON), silicon carbide (SiC), and/or the like. However, it should be appreciated that the BDI layer 104 may include other suitable materials. Moreover, in some embodiments, the BDI layer 104 may be omitted. Also, the nanosheet stack NS patterning process is performed with a hardmask (not shown) and any suitable combination of lithographic and material removal operations. In the nanosheet patterning process, any suitable material removal process (e.g., reactive ion etching (RIE)) may be used to remove the various layers of the nanosheet stack NS down to the level of the bottom dielectric isolation layer 104. Following the patterning process for the nanosheet stack 103 (e.g., all of the sacrificial layers 106 and semiconductor layers 108) the hardmask is removed.

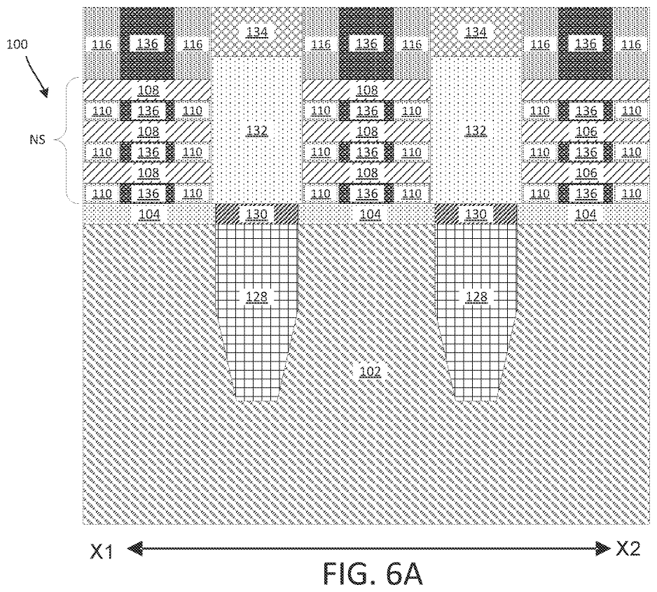

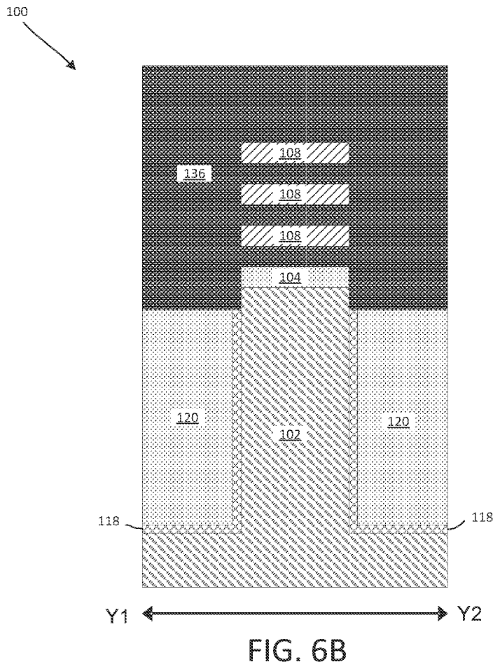

As also shown in FIGS. 2A and 2B, a dummy gate 114 (or sacrificial gate) is formed on the top of the nanosheet stack NS by any suitable deposition and/or patterning processes known to one of skill in the art. In one example, the dummy gate 114 is formed by depositing a thin SiO₂ dummy gate oxide layer (or sacrificial oxide layer), followed by depositing a layer of amorphous silicon (a-Si) as the dummy gate 114. The dummy gate 114 may be composed of polycrystalline silicon (poly silicon), amorphous silicon, and/or an oxide, such as, SiO₂. A gate hardmask (not shown) may also formed on a top side of the dummy gate 114. The gate hardmask may be formed for subsequent nanosheet patterning. The gate hardmask can be composed of various nitride materials including, but not limited to, a nitride, an oxide, silicon nitride (SiN), and/or a combination of a nitride material and an oxide material. In certain embodiments, as shown in FIG. 2A, the dummy gate 114 extends into and out of the page to wrap around the edges of the nanosheet stack NS, and the subsequent removal of the dummy gate 114 (see, FIGS. 6A and 6B) allows an access point for later removal of the sacrificial layers 106.

As shown in FIG. 2A, a spacer 116 (or spacer layer, or gate spacer) is formed on the sidewalls of the patterned dummy gate 114. In certain examples, the spacer 116 is formed to cover the topmost active semiconductor layer 108 of the nanosheet stack NS. Then, the semiconductor device 100 is subjected to a directional reactive ion etch (RIE) process, which selectively removes portions of the sacrificial layers 106. The RIE can use a boron-based chemistry or a chlorine-based chemistry, for example, which selectively recesses the exposed portions sacrificial layers 106 without significantly removing the active semiconductor layers 108. Thus, portions of the sacrificial layers 106 are recessed in an inward direction (i.e., an inner spacer indentation process) so that the processed widths of the sacrificial layers 106 are less than widths of the active semiconductor layers 108.

As also shown in FIG. 2A, inner spacers 110 are added in the recesses that were previously formed into the sacrificial layers 106. In certain embodiments, after the formation of the inner spacers 110, an isotropic etch process is performed to create outer vertical edges to the inner spacers 110 that align with outer vertical edges of the active semiconductor layers 108. In certain embodiments, the material of the inner spacer 110 is a dielectric material such as SiN, SiO, SiBCN, SiOCN, SiCO, etc.

As shown in FIG. 2B, a nitride layer 118 and shallow trench isolation (STI) layer 120 may be formed into the semiconductor substrate 102. In general, shallow trench isolation is an integrated circuit feature which prevents electric current leakage between adjacent semiconductor device components. STI is generally used on CMOS process technology nodes of 250 nanometers and smaller. STI regions 120 are created early during the semiconductor device fabrication process before transistors are formed. The STI process involves etching a pattern of trenches in the silicon, depositing one or more dielectric materials (such as the nitride layer 118 and STI layer 120) to fill the trenches, and removing the excess dielectric using a technique such as chemical-mechanical planarization. As also shown in FIG. 2B, the material of the dummy electrode 114 is formed to cover the nanosheet stack NS.

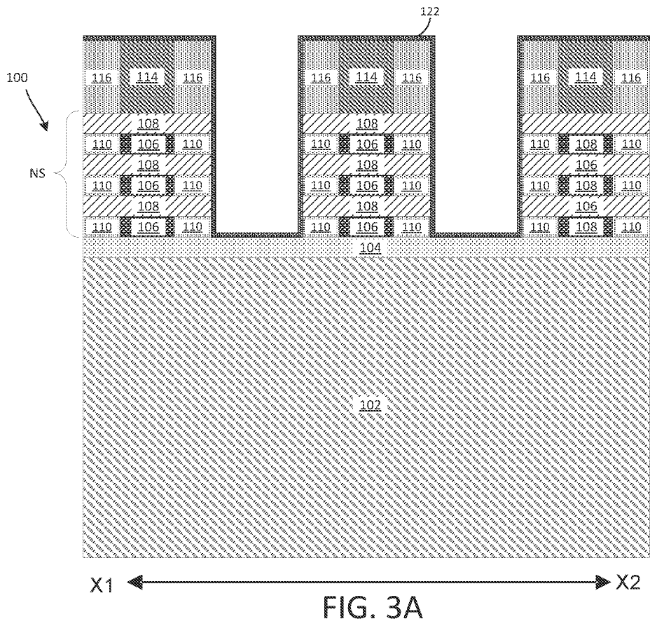

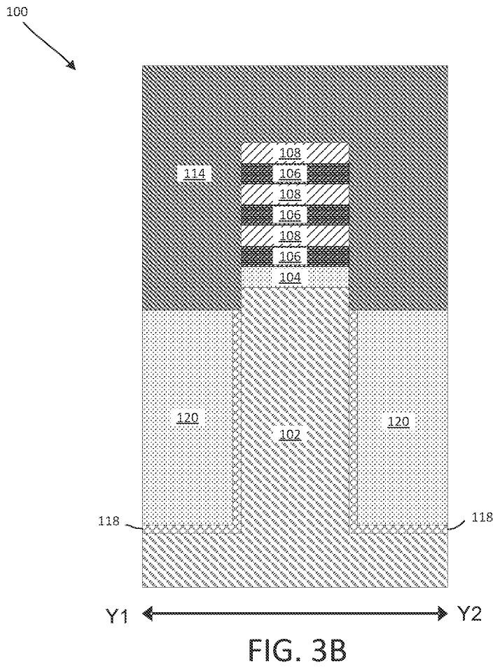

Referring now to FIGS. 3A and 3B, FIG. 3A is a cross-sectional view of the semiconductor device 100 of FIG. 2A at a subsequent stage of the fabrication process, taken along the line X1-X2 of FIG. 1B, and FIG. 3B is a cross-sectional view of the semiconductor device 100 of FIG. 2B at a subsequent stage of the fabrication process, taken along the line Y1-Y2 of FIG. 1B. As shown in FIG. 3A, a liner layer 122 is conformally deposited to cover the bottom dielectric isolation layer 104, the sidewalls of the nanosheet stack NS, and the exposed surfaces of the dummy electrode 114 and the spacer 116. Note that in the cross-sectional view shown in FIG. 3B, the liner layer 122 does not cover the sidewalls of the nanosheet stack NS or the bottom dielectric isolation layer 104 because they are already covered by the dummy gate 114. In certain examples, the liner layer 122 may comprise one or more suitable oxide materials.

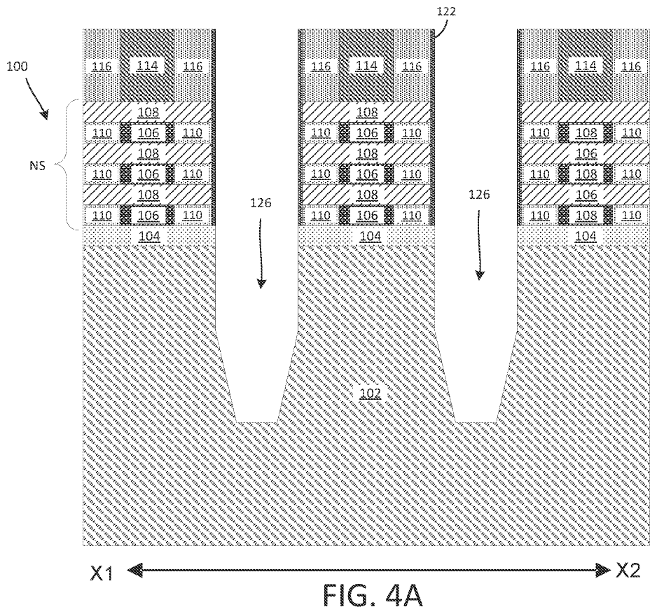

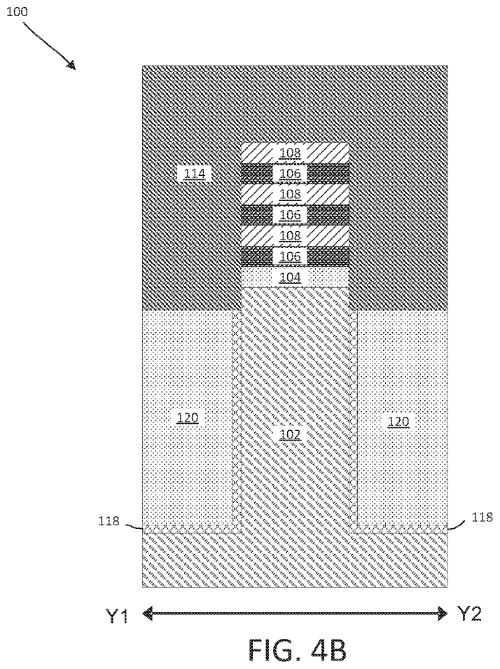

Referring now to FIGS. 4A and 4B, FIG. 4A is a cross-sectional view of the semiconductor device 100 of FIG. 3A at a subsequent stage of the fabrication process, taken along the line X1-X2 of FIG. 1B, and FIG. 4B is a cross-sectional view of the semiconductor device 100 of FIG. 3B at a subsequent stage of the fabrication process, taken along the line Y1-Y2 of FIG. 1B. As shown in FIG. 4A, a suitable material removal process, such as reactive ion etching (RIE) is to remove the horizontal portions of the liner layer 122, and also to create a placeholder trench 126 that is formed by removing portions of the bottom dielectric isolation layer 104 and the substrate 102 that are not covered by the nanosheet stacks NS. The placeholder trench 126 will allow for subsequent formation of the placeholder layer 128.

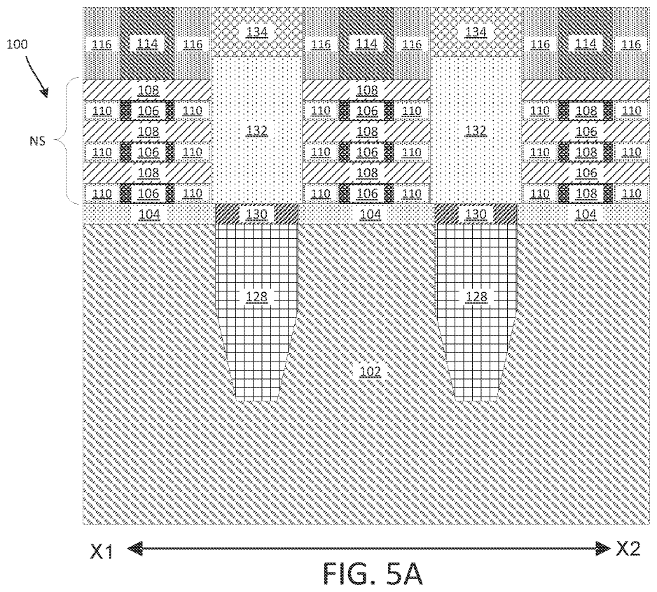

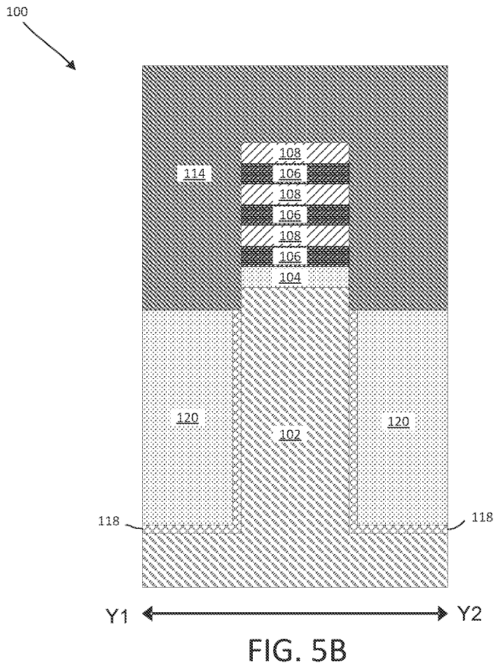

Referring now to FIGS. 5A and 5B, FIG. 5A is a cross-sectional view of the semiconductor device 100 of FIG. 4A at a subsequent stage of the fabrication process, taken along the line X1-X2 of FIG. 1B, and FIG. 5B is a cross-sectional view of the semiconductor device 100 of FIG. 4B at a subsequent stage of the fabrication process, taken along the line Y1-Y2 of FIG. 1B. As shown in FIG. 5A, a placeholder layer 128 is formed in the previously formed placeholder trench 126. In certain examples, the placeholder layer 128 may comprise SiGe. However, it should be appreciated that other suitable materials other than SiGe may be used for the placeholder layers 128. In this example, the placeholder layer 128 is formed to a height that roughly corresponds to an interface between the substrate 102 and the BDI layer 104. However, it should be appreciated that in other examples the height of the placeholder layer 128 may be slightly higher or lower than that which is shown in FIG. 5A. As will be explained in further detail below, the placeholder layer 128 on the right side of FIG. 5A (i.e., the X2 side) will be removed to allowed for the formation of other structures, whereas the placeholder layer 128 on the left side (i.e., the X1 side) will not be removed. It should be appreciated that the placeholder layer 128 on the left side will not serve as an active component in the functioning the semiconductor device 100. In certain examples, a silicon layer 130 is deposited on the placeholder layer. The silicon layer 130 may function as a barrier layer between the placeholder layer 128 and the epitaxial layers. There are no differences between FIGS. 5B and 4B.

As also shown in FIG. 5A, an epitaxial layer 132 is formed to cover the sidewalls of the nanosheet stack NS. The epitaxial layer 132 forms a junction in the semiconductor device 100. In certain embodiments, the epitaxial layer 132 may be a source/drain epitaxial layer of a p-type or an n-type, and it is deposited by an epitaxial growth method up to at least the level of the top of the nanosheet stack NS (or slightly higher, as shown in FIG. 5A). In certain embodiments, the material of the epitaxial layer 124 may be, for example, Si—P or Si/P based. However, it should be appreciated that any other suitable materials may be used.

As also shown in FIG. 5A, an interlayer dielectric (ILD) layer 134 is formed around the nanosheet stack NS up to the level of the top of the dummy gate 114. In certain examples, a planarization process such as CMP may be performed to create a planar surface for the semiconductor device 100 after the formation of the ILD layer 134. The ILD layer 134 can be any suitable material, such as, for example, porous silicates, carbon doped oxides, silicon dioxides, silicon nitrides, silicon oxynitrides, or other dielectric materials. Any known manner of forming the ILD layer 134 can be utilized. The ILD layer 134 can be formed using, for example, CVD, plasma enhanced chemical vapor deposition (PECVD), ALD, flowable CVD, spin-on dielectrics, or PVD.

Referring now to FIGS. 6A and 6B, FIG. 6A is a cross-sectional view of the semiconductor device 100 of FIG. 5A at a subsequent stage of the fabrication process, taken along the line X1-X2 of FIG. 1B, and FIG. 6B is a cross-sectional view of the semiconductor device 100 of FIG. 5B at a subsequent stage of the fabrication process, taken along the line Y1-Y2 of FIG. 1B. As shown in FIGS. 6A and 6B, following the formation of the ILD layer 134, a selective removal of the dummy gate 114 and the sacrificial layers 106 (i.e., the SiGe suspensions) is performed, and these layers are replaced with the gate 136. The dummy gate 114 is removed by any suitable material removal process known to one of skill in the art. For example, such removal may be accomplished by an etching process which may include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist. Then, the sacrificial layers 106 are removed (or released).

Although not shown in FIGS. 6A and 6B, immediately after the removal of the sacrificial layers 106, there are void spaces between the active semiconductor layers 108 due to the removal of the sacrificial layers 106. It should be appreciated that during the removal of the dummy gate 114 and the sacrificial layers 106, appropriate etchants are used that are selective to the sacrificial layers 106 and dummy gate 114, but that do not significantly remove material of the semiconductor layers 108, the silicon layer 130 or the inner spacers 110 (i.e., the etchants are selected to selectively remove the material of the dummy gate 114 and sacrificial layers 106). The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include tetrafluoromethane (CF₄), nitrogen trifluoride (NF₃), sulfur hexafluoride (SF₆), helium (He), and chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), tetrafluoromethane (CF₄), or a gas mixture with hydrogen (H₂). Chemical vapor etching can be performed by CVD with suitable pressure and temperature.

Then, as shown in FIGS. 6A and 6B, the gate 136 (or gate electrode, or work function metal (WFM) layer) is formed in the void spaces that were created by the previous removal of the dummy gate 114 and the sacrificial layers 106. In certain embodiments, the gate 136 includes a WFM material that may be a p-type material or an n-type material. The gate 136 can be comprised of metals, such as, e.g., copper (Cu), cobalt (Co), aluminum (Al), platinum (Pt), gold (Au), tungsten (W), titanium (Ti), nitrides, or any combination thereof. The metal can be deposited by a suitable deposition process, for example, CVD, PECVD, PVD, plating, thermal or e-beam evaporation, or sputtering. In various exemplary embodiments, the height of the gate 136 can be reduced by CMP and/or etching. Therefore, the planarization process can be provided by CMP. Other planarization process can include grinding and polishing. In general, the work function metal material of the gate 136 sets the threshold voltage (Vₜₕ) of the device, a high-κ gate dielectric material (not shown) may be provided that separates the WFM material of the gate 136 from the semiconductor layers 108 of the nanosheet stacks NS, and other metals that may be desired to further fine tune the effective work function (eWF) and/or to achieve a desired resistance value associated with current flow through the gate stack in the direction parallel to the plane of the nanosheets may be used. Thus, the gate 136, the epitaxial layer 132 and the nanosheet stack NS, and the various metal contacts form a nanosheet field effect transistor (FET), which could be a p-type device or an n-type device.

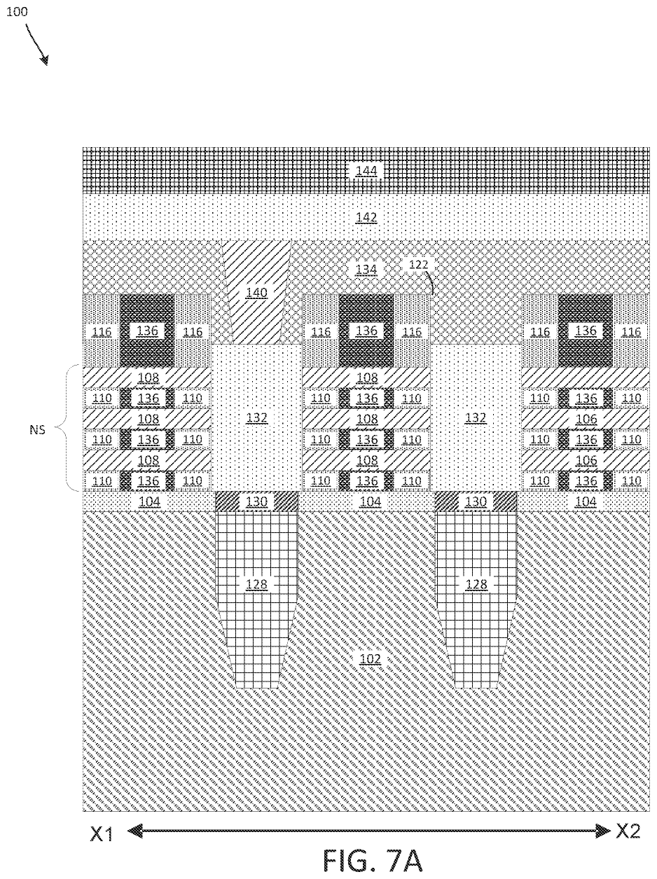

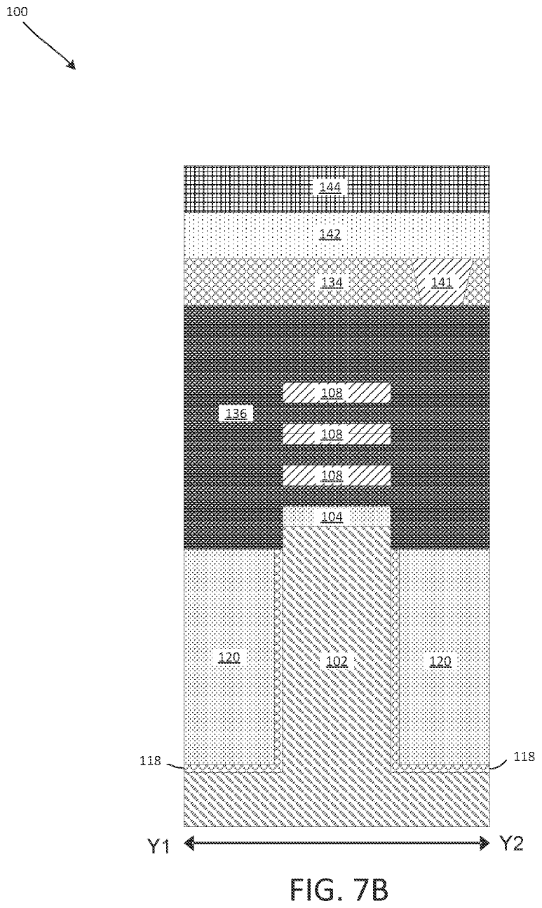

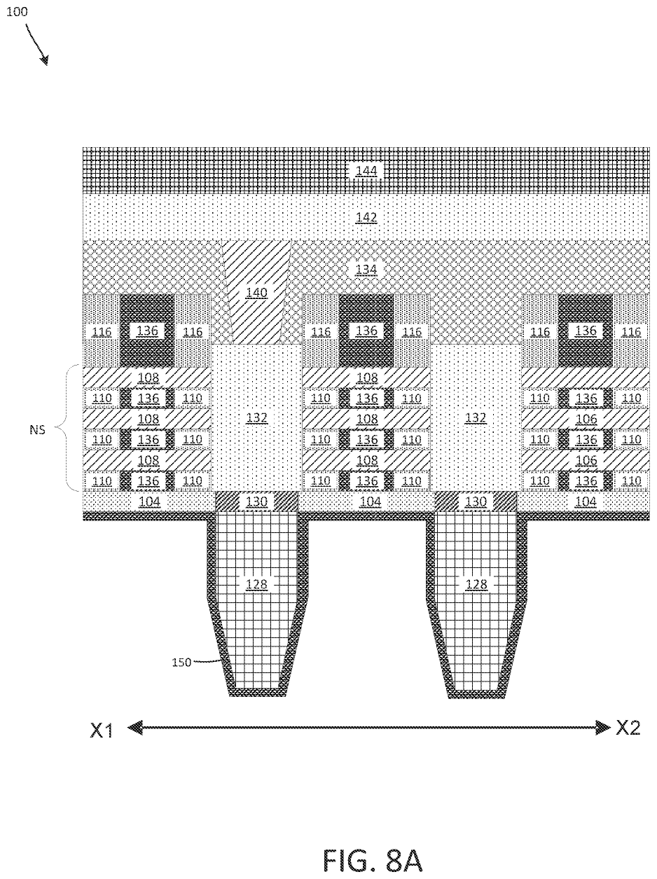

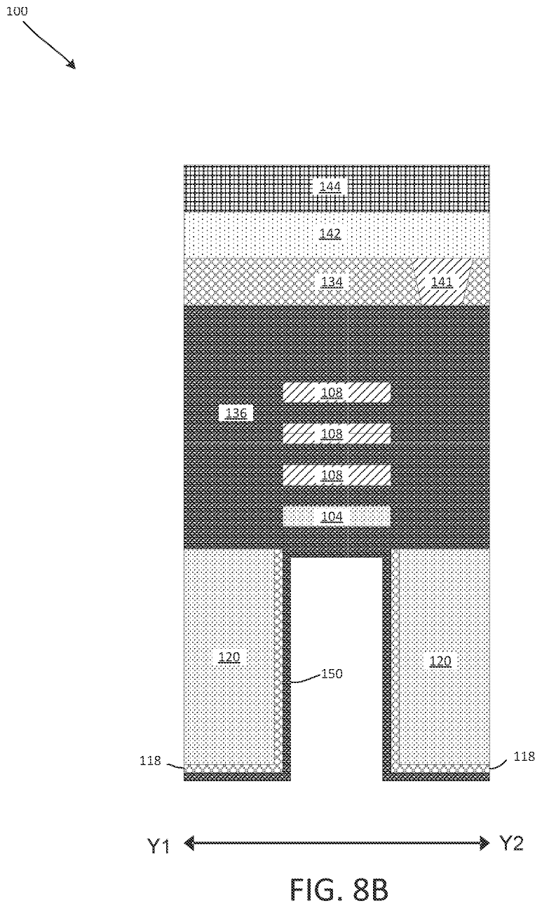

Referring now to FIGS. 7A and 7B, FIG. 7A is a cross-sectional view of the semiconductor device 100 of FIG. 6A at a subsequent stage of the fabrication process, taken along the line X1-X2 of FIG. 1B, and FIG. 7B is a cross-sectional view of the semiconductor device 100 of FIG. 6B at a subsequent stage of the fabrication process, taken along the line Y1-Y2 of FIG. 1B. As shown in FIGS. 7A and 7B, additional material of the ILD layer 134 is deposited to increase the thickness of the ILD layer 134 above the level of the top surface of the gate 136. The additional material of the ILD layer 134 allows for covering the top surface of the gate 136 and for subsequent metal contact formation. After the formation of the ILD layer 134, a suitable material removal process is utilized to form trenches (not shown) in the ILD layer 134. Then, a first metal contact 140 (sometimes referred to as a CA contact) is formed on the epitaxial layer 132, as shown in FIG. 7A. At the same time, a second metal contact 141 (sometimes referred to as a CB contact) is formed on the gate 135, as shown in FIG. 7B. In the example shown in FIG. 8A, the first contact 140 is formed on the left side (i.e., the X1 side) of the semiconductor device 100, but not on the right side (i.e., the X2 side). This will allow for subsequent formation of a backside contact that connects to the epitaxial layer 132 on the right side after the placeholder layer 128 on the right side is removed. In subsequent processing steps, a back end of line (BEOL) layer 142 is formed on the ILD layer 134 and on the first metal contact 140 and second metal contact 141. As mentioned above, the BEOL layer 142 (or BEOL region) is the second portion of IC fabrication where the individual devices (transistors, capacitors, resistors, etc.) get interconnected with wiring on the wafer. Next, in certain embodiments, a heat sink 144 (e.g., a handler wafer) is attached to the semiconductor device 100 on the top of the BEOL layer 142. In general, a heat sink refers to any suitable device or substance for absorbing excessive or unwanted heat.

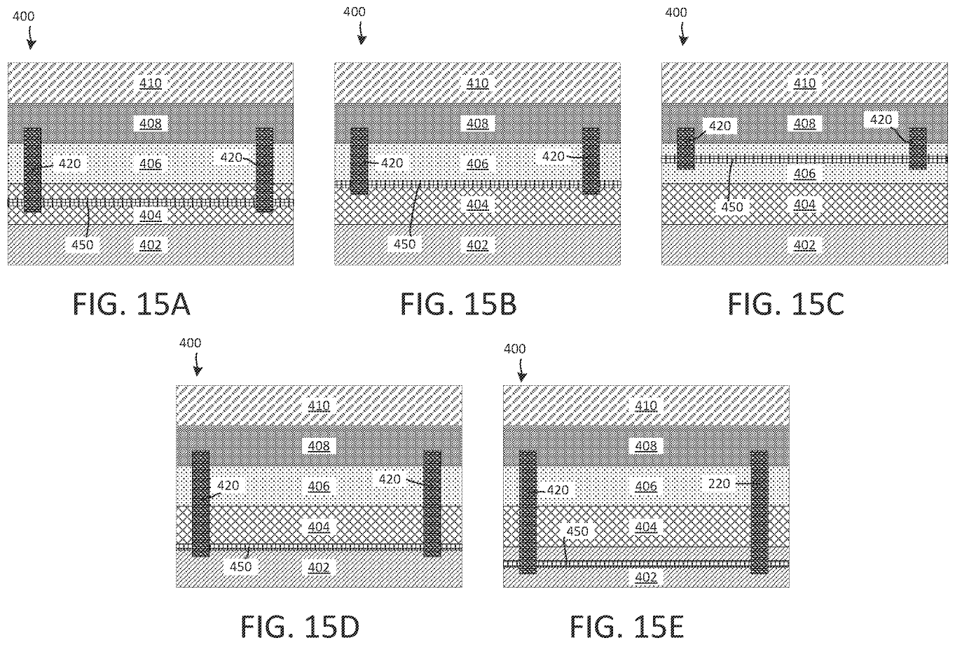

Referring now to FIGS. 8A and 8B, FIG. 8A is a cross-sectional view of the semiconductor device 100 of FIG. 7A at a subsequent stage of the fabrication process, taken along the line X1-X2 of FIG. 1B, and FIG. 8B is a cross-sectional view of the semiconductor device 100 of FIG. 7B at a subsequent stage of the fabrication process, taken along the line Y1-Y2 of FIG. 1B. As shown in FIGS. 8A and 8B, the substrate 102 is removed with any suitable material removal process, such as RIE. This temporarily exposes the placeholder layer 128 and the BDI layer 104. Then, a high thermal conductivity dielectric layer 150 is formed to cover the placeholder layer 128 and the BDI layer 104. The high thermal conductivity dielectric layer 150 may comprise, for example, hexagonal boron nitride (hBN), which is a stable crystalline form of boron nitride which has a layered structure similar to graphite. hBN is known for its high thermal conductivity, but it also has the properties of an insulator. Thus, the high thermal conductivity dielectric layer 150 allows for an insulating layer to be integrated into the device (this is important to prevent electrical shorting between adjacent transistors) that also is capable of effectively transferring heat away from the device. Although not shown in FIG. 8A (the scale of the cross-sectional view in FIG. 8A does not permit illustration of same), the high thermal conductivity dielectric layer 150 is connected to a heat transfer pillar (see, heat transfer pillar 420 in FIGS. 15A-15E), which in turn transfers the heat upward towards a cooling module (see, heat exchanger 410 in FIGS. 15A-15E). As shown in FIG. 8B, the high thermal conductivity dielectric layer 150 covers the nitride layer 118.

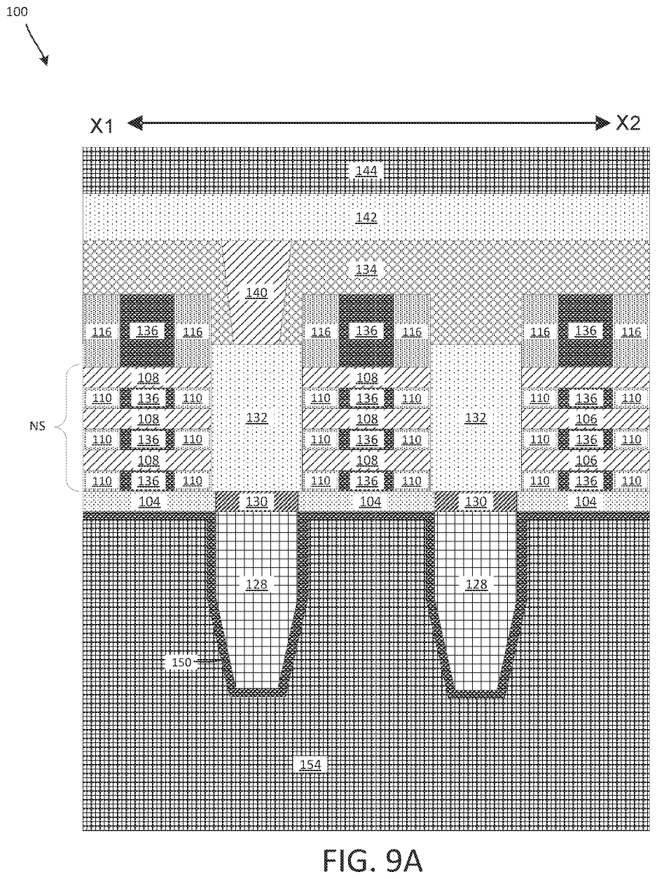

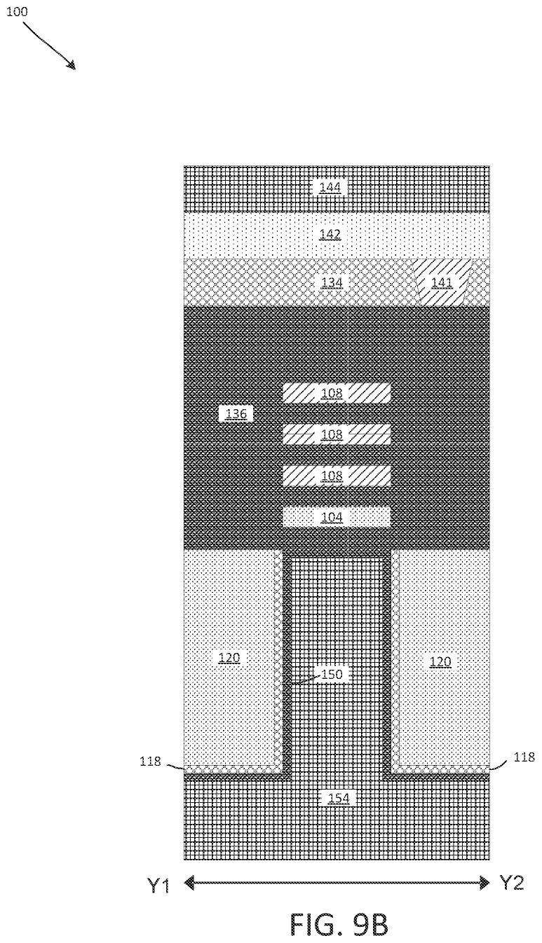

Referring now to FIGS. 9A and 9B, FIG. 9A is a cross-sectional view of the semiconductor device 100 of FIG. 8A at a subsequent stage of the fabrication process, taken along the line X1-X2 of FIG. 1B, and FIG. 9B is a cross-sectional view of the semiconductor device 100 of FIG. 8B at a subsequent stage of the fabrication process, taken along the line Y1-Y2 of FIG. 1B. As shown in FIGS. 9A and 9B, a bottom ILD layer 154 is formed on the high thermal conductivity dielectric layer 150.

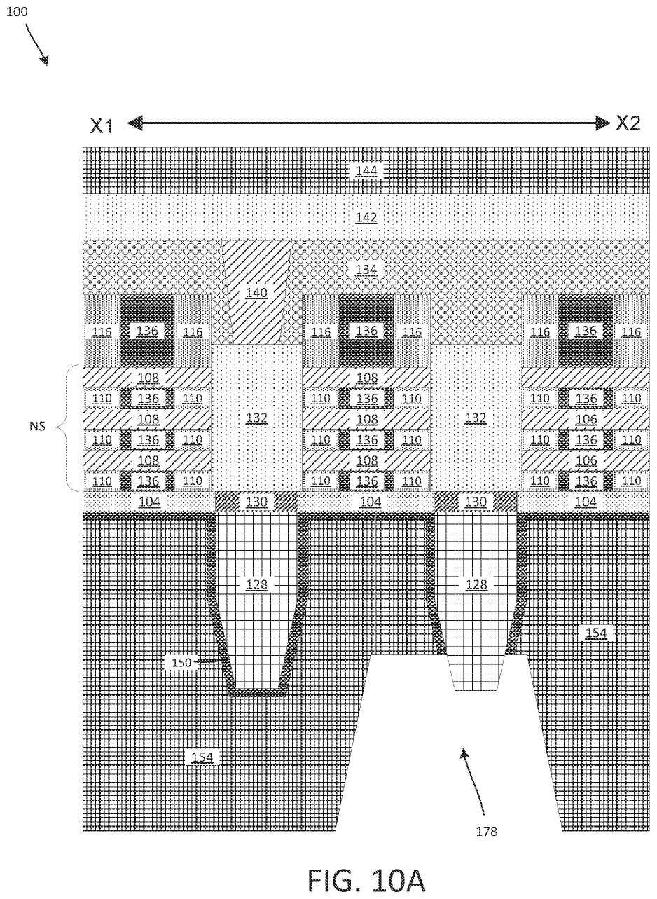

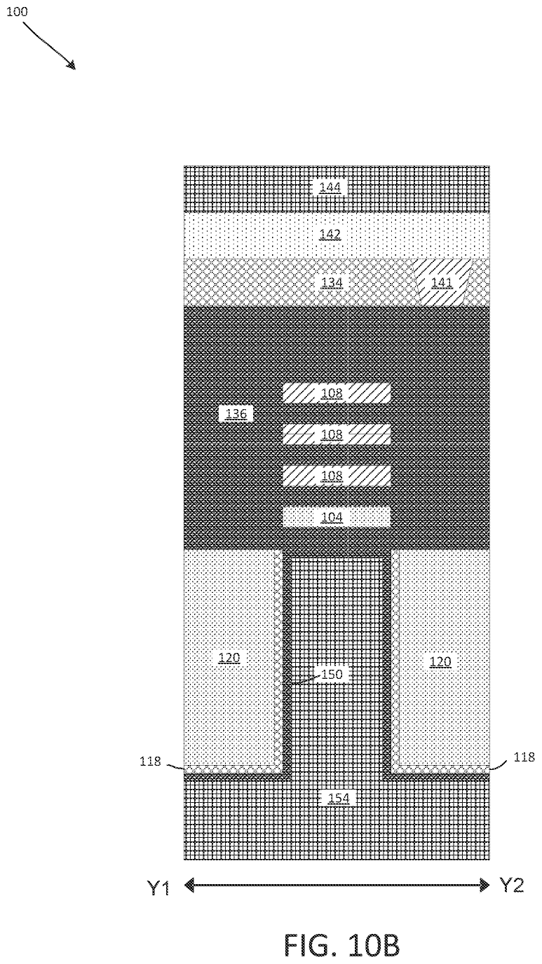

Referring now to FIGS. 10A and 10B, FIG. 10A is a cross-sectional view of the semiconductor device 100 of FIG. 9A at a subsequent stage of the fabrication process, taken along the line X1-X2 of FIG. 1B, and FIG. 10B is a cross-sectional view of the semiconductor device 100 of FIG. 9B at a subsequent stage of the fabrication process, taken along the line Y1-Y2 of FIG. 1B. As shown in FIG. 10A, a suitable material removal process is used to form a backside contact opening 178 is formed in the bottom ILD layer 154. The backside contact opening 178 is formed to a sufficient depth to expose a portion of the placeholder layer 128 on the right side (i.e., the X2 side) of the semiconductor device, as shown in FIG. 10A. This material removal process also removes a portion of the high thermal conductivity dielectric layer 150 in the area where the placeholder layer 128 is exposed. This material removal step allows for the subsequent removal of the placeholder layer 128 on the right side, which will be replaced with the back side contact.

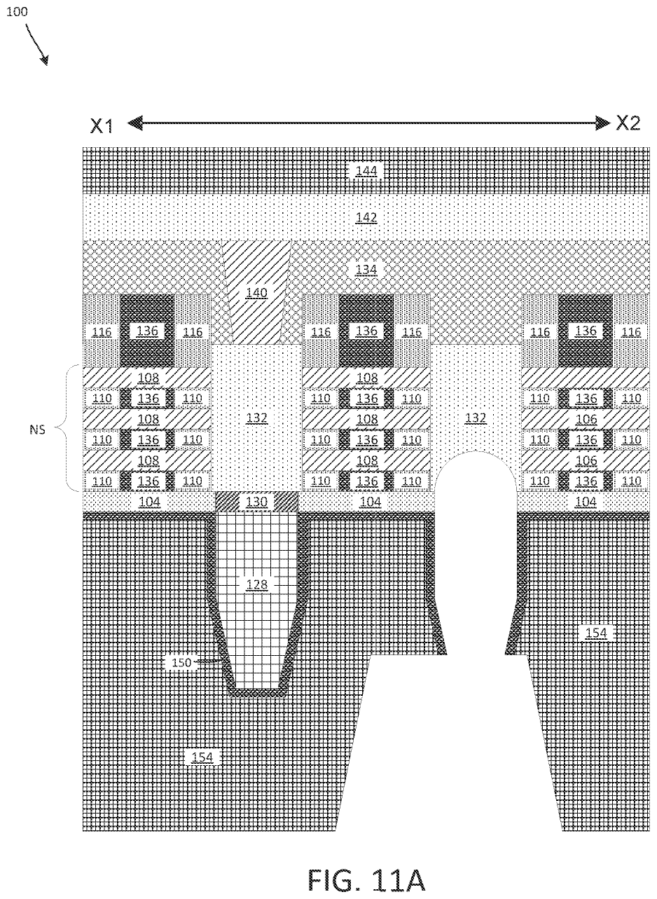

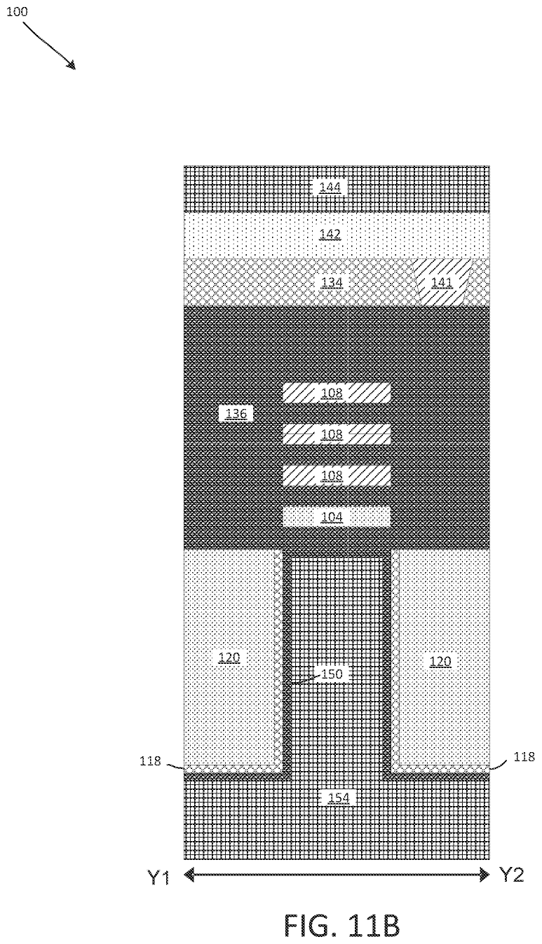

Referring now to FIGS. 11A and 11B, FIG. 11A is a cross-sectional view of the semiconductor device 100 of FIG. 10A at a subsequent stage of the fabrication process, taken along the line X1-X2 of FIG. 1B, and FIG. 11B is a cross-sectional view of the semiconductor device 100 of FIG. 10B at a subsequent stage of the fabrication process, taken along the line Y1-Y2 of FIG. 1B. As shown in FIG. 11A, one or more suitable material processes is used to remove the placeholder layer 128 on the right side, to remove the silicon layer 130 on the right side, and to remove a portion of the epitaxial layer 132 on the right side. It should be appreciated that two or more different material removal processes may be utilized in sequence to the remove these different layers. Thus, at this stage of the manufacturing process, the backside (or bottom side) of the epitaxial layer 132 on the right side is exposed to allow for the subsequent formation of a backside contact.

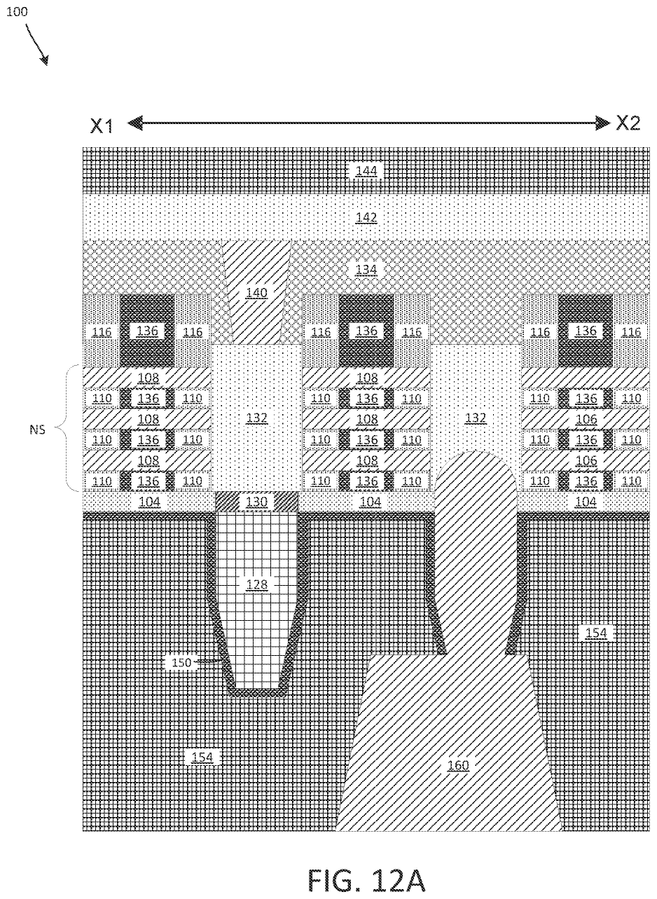

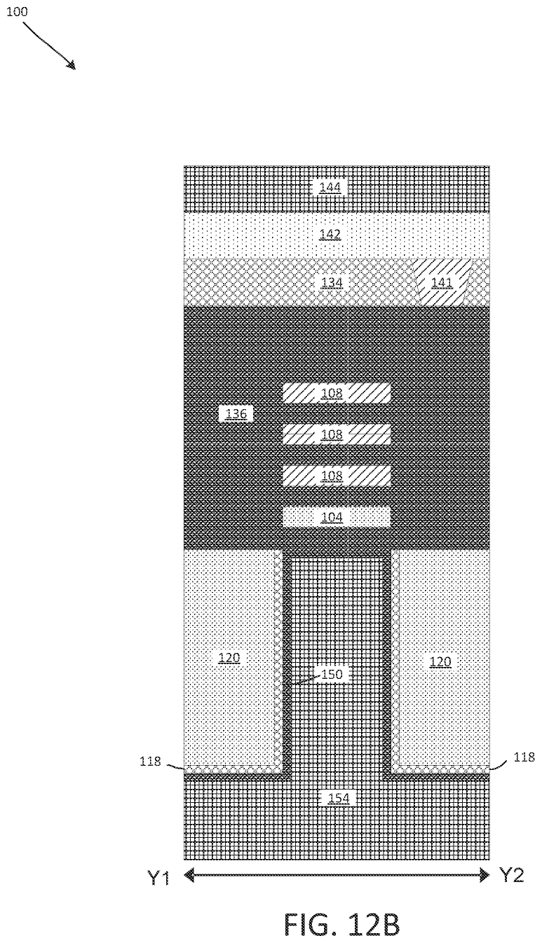

Referring now to FIGS. 12A and 12B, FIG. 12A is a cross-sectional view of the semiconductor device 100 of FIG. 11A at a subsequent stage of the fabrication process, taken along the line X1-X2 of FIG. 1B, and FIG. 12B is a cross-sectional view of the semiconductor device 100 of FIG. 11B at a subsequent stage of the fabrication process, taken along the line Y1-Y2 of FIG. 1B. As shown in FIG. 12A, a backside metal contact 154 (sometimes referred to as BSCA) is formed in contact with the epitaxial layer 132 on the right side. Thus, with reference to the contacts, FIG. 12A shows that the first contact 140 is formed in contact with the top surface of the epitaxial layer 132 on the left side, and the backside metal contact 154 is formed on the bottom surface of the epitaxial layer 132 on the right side. Moreover, the presence of the high thermal conductivity dielectric layer 150 allows for effective heat transfer from the various transistors in the context of a backside power distribution network (BSPDN). As discussed above, with semiconductor devices 100, the use of a BSPDN may result in about a 15% increase in thermal resistance relative to semiconductor device that use a frontside power distribution network (FSPDN). Therefore, the high thermal conductivity dielectric layer 150 allows for the implementation of a BSPDN with increased thermal transfer properties, thereby enabling a more optimal operating temperature for the various transistors of the device.

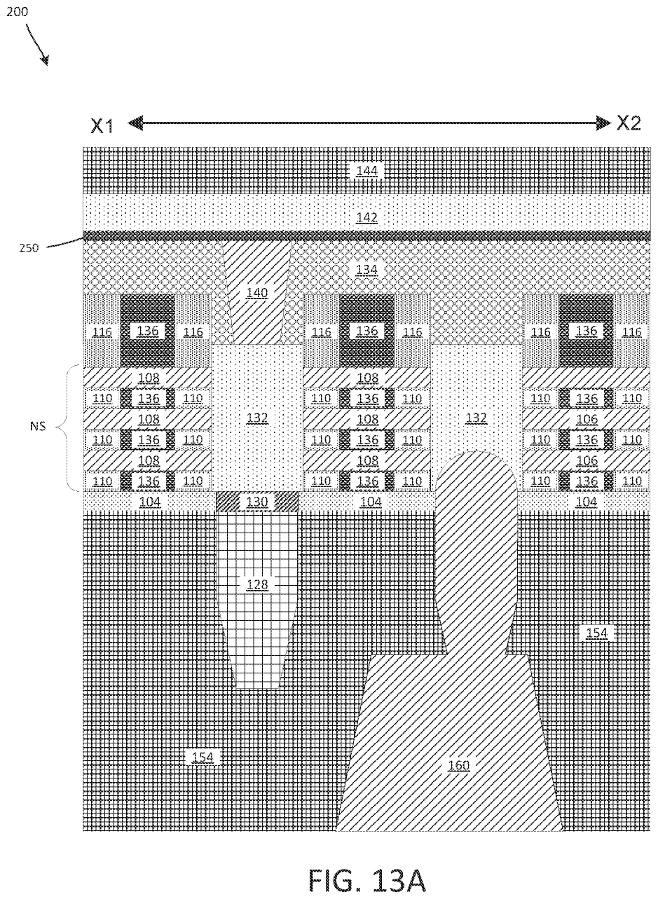

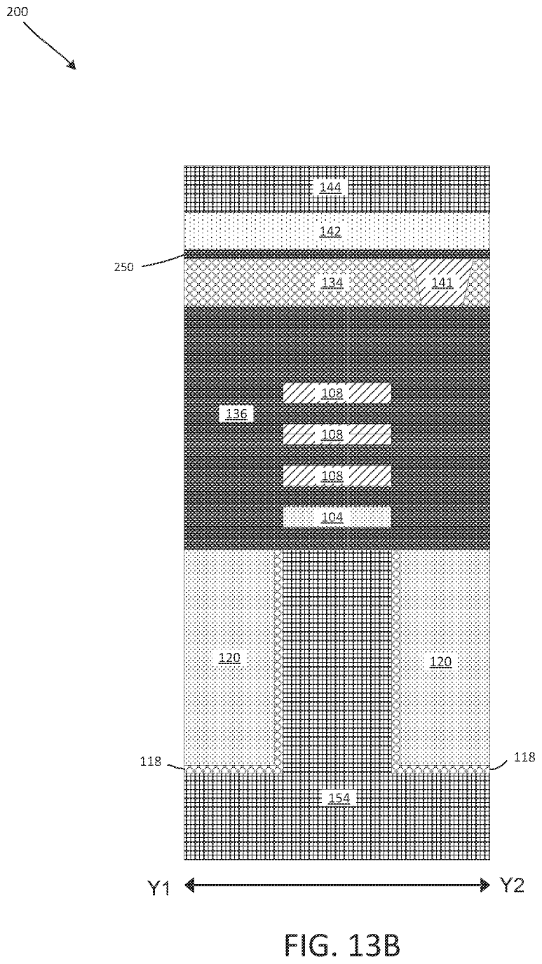

Referring now to FIGS. 13A and 13B, FIG. 13A is a cross-sectional view of a semiconductor device 200 similar to that shown in FIG. 12A, but where the placement of the high thermal conductivity dielectric layer 250 is different than the high thermal conductivity dielectric layer 150 shown in FIG. 12A. The high thermal conductivity dielectric layer 250 may comprise, for example, hBN, and may be the same material as the high thermal conductivity dielectric layer 150 shown in FIG. 12A. As shown in FIG. 13A, the high thermal conductivity dielectric layer 250 is located between the ILD layer 134 and the BEOL layer 142. The different placement of the high thermal conductivity dielectric layer 250 allows for increased manufacturing flexibility while still enabling efficient transfer of heat. It should be appreciated that the shape of the high thermal conductivity dielectric layer 250 shown in FIGS. 13A and 13B is flat/planar, as opposed to the irregular non-planar profile of the high thermal conductivity dielectric layer 150 shown in FIGS. 1A-12B, which follows the contour of several other layers (e.g., the placeholder layer 128).

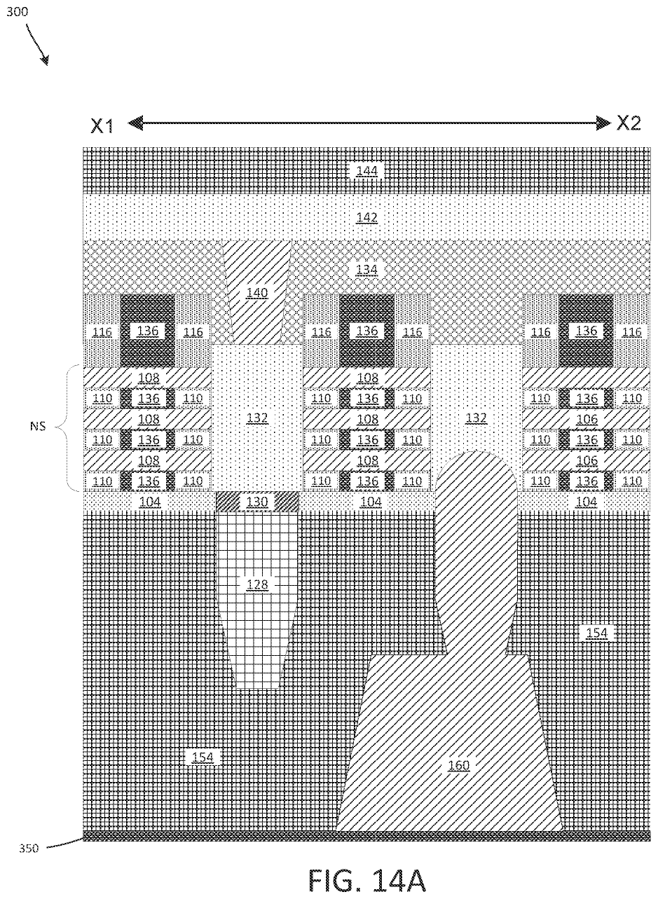

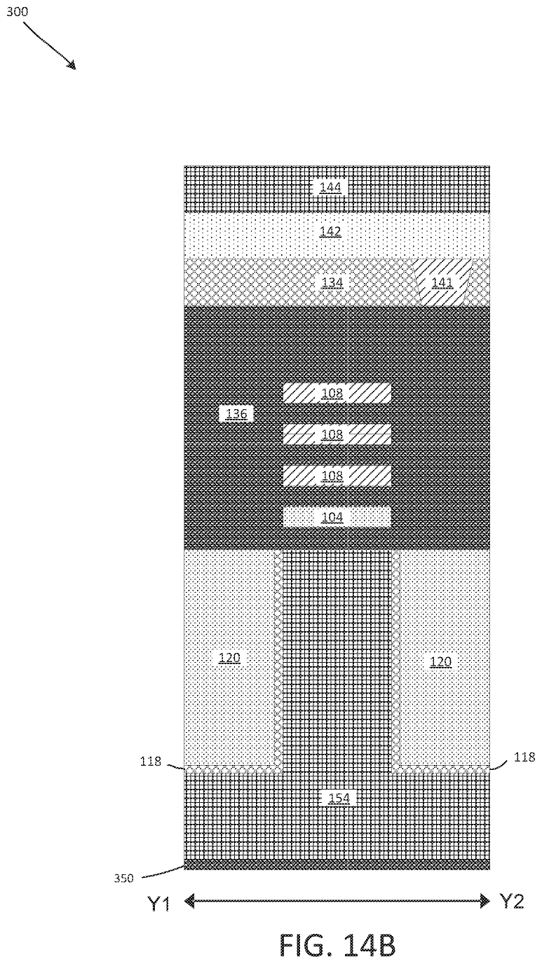

Referring now to FIGS. 14A and 14B, FIG. 14A is a cross-sectional view of a semiconductor device 300 similar to that shown in FIG. 12A, but where the placement of the high thermal conductivity dielectric layer 350 is different than the high thermal conductivity dielectric layer 150 shown in FIG. 12A. The high thermal conductivity dielectric layer 350 may comprise, for example, hBN, and may be the same material as the high thermal conductivity dielectric layer 150 shown in FIG. 12A. As shown in FIG. 14A, the high thermal conductivity dielectric layer 350 is located on the bottom of the bottom ILD layer 154. The different placement of the high thermal conductivity dielectric layer 350 allows for increased manufacturing flexibility while still enabling efficient transfer of heat.

Referring now to FIG. 15A, this figure is a simplified cross-sectional view of a semiconductor device 400 including a high thermal conductivity dielectric layer 450 that contacts a vertical heat transfer pillar 420, according to embodiments. As discussed above with respect to FIGS. 1A-14B, the scale of those figures does not permit illustration of how the high thermal conductivity dielectric layer connects to a vertical heat transfer pillar, and therefore FIGS. 15A-15E present a simplified schematic view that illustrates these additional features. Thus, the concepts described with respect to FIGS. 15A-15E apply to any of the examples shown in FIGS. 1A-14B.

As shown in FIG. 15A, the semiconductor device 400 includes a backside power distribution network (BSPDN) 402, a front end of line (FEOL) region 404 on the BSPDN 402, a middle of line/back end of line (MOL/BEOL) region 406 on the FEOL region 404, a heat sink 408 on the MOL/BEOL region 406, and a heat exchanger 410 on the heat sink 408. It should be appreciated that the BSPDN 402, the FEOL region 404 and the MOL/BEOL region 406 may each include a plurality of separate layers. The heat exchanger 410 may be any suitable device able to transfer heat away from the semiconductor device 400 (e.g., a cooling fan, or liquid cooling mechanism). As shown in FIG. 15A, the semiconductor device 400 also includes a high thermal conductivity dielectric layer 450 positioned within the FEOL region 404. The semiconductor device also includes a heat transfer pillar 420 that contacts the high thermal conductivity dielectric layer 450. In this example, the heat transfer pillar 420 extends at least partially through the FEOL region 404, through the MOL/BEOL region 406, and at least partially through the heat sink 408. Thus, effective heat transfer may be achieved with heat transferring from one or more heat generating sources, through the high thermal conductivity dielectric layer 450, then through the heat transfer pillar 420, then through the heat sink 408 to the heat exchanger 410.

Referring now to FIG. 15B, this figure is a simplified cross-sectional view of a semiconductor device 400 including a high thermal conductivity dielectric layer 450 that contacts a heat transfer pillar 420, according to embodiments. FIG. 15B differs from FIG. 15A with respect to the location of the high thermal conductivity dielectric layer 450 and the height of the heat transfer pillar 420. As shown in FIG. 15B, the semiconductor device 400 also includes a high thermal conductivity dielectric layer 450 positioned at an interface of the FEOL region 404 and the MOL/BEOL region 408. The semiconductor device also includes a heat transfer pillar 420 that contacts the high thermal conductivity dielectric layer 450. In this example, the heat transfer pillar 420 extends through the MOL/BEOL region 406, and at least partially through the heat sink 408. Thus, effective heat transfer may be achieved with heat transferring from one or more heat generating sources, through the high thermal conductivity dielectric layer 450, then through the heat transfer pillar 420, and then through the heat sink 408 to the heat exchanger 410.

Referring now to FIG. 15C, this figure is a simplified cross-sectional view of a semiconductor device 400 including a high thermal conductivity dielectric layer 450 that contacts a heat transfer pillar 420, according to embodiments. FIG. 15C differs from FIG. 15A with respect to the location of the high thermal conductivity dielectric layer 450 and the height of the heat transfer pillar 420. As shown in FIG. 15C, the semiconductor device 400 also includes a high thermal conductivity dielectric layer 450 positioned within the MOL/BEOL region 408. The semiconductor device also includes a heat transfer pillar 420 that contacts the high thermal conductivity dielectric layer 450. In this example, the heat transfer pillar 420 extends through a portion of the MOL/BEOL region 406, and at least partially through the heat sink 408. Thus, effective heat transfer may be achieved with heat transferring from one or more heat generating sources, through the high thermal conductivity dielectric layer 450, then through the heat transfer pillar 420, and then through the heat sink 408 to the heat exchanger 410.

Referring now to FIG. 15D, this figure is a simplified cross-sectional view of a semiconductor device 400 including a high thermal conductivity dielectric layer 450 that contacts a heat transfer pillar 420, according to embodiments. FIG. 15D differs from FIG. 15A with respect to the location of the high thermal conductivity dielectric layer 450 and the height of the heat transfer pillar 420. As shown in FIG. 15D, the semiconductor device 400 also includes a high thermal conductivity dielectric layer 450 positioned at an interface of the BSPDN 402 and the FEOL region 404. The semiconductor device 400 also includes a heat transfer pillar 420 that contacts the high thermal conductivity dielectric layer 450. In this example, the heat transfer pillar 420 extends at least partially through the BSPDN 402, through the FEOL region 404, through the MOL/BEOL region 406, and at least partially through the heat sink 408. Thus, effective heat transfer may be achieved with heat transferring from one or more heat generating sources, through the high thermal conductivity dielectric layer 450, then through the heat transfer pillar 420, and then through the heat sink 408 to the heat exchanger 410.

Referring now to FIG. 15E, this figure is a simplified cross-sectional view of a semiconductor device 400 including a high thermal conductivity dielectric layer 450 that contacts a vertical heat transfer pillar 420, according to embodiments. FIG. 15E differs from FIG. 15A with respect to the location of the high thermal conductivity dielectric layer 450 and the height of the heat transfer pillar 420. As shown in FIG. 15D, the semiconductor device 400 also includes a high thermal conductivity dielectric layer 450 positioned within the BSPDN 402 and the FEOL region 404. The semiconductor device 400 also includes a heat transfer pillar 420 that contacts the high thermal conductivity dielectric layer 450. In this example, the heat transfer pillar 420 extends at least partially through the BSPDN 402, through the FEOL region 404, through the MOL/BEOL region 406, and at least partially through the heat sink 408. Thus, effective heat transfer may be achieved with heat transferring from one or more heat generating sources, through the high thermal conductivity dielectric layer 450, then through the heat transfer pillar 420, and then through the heat sink 408 to the heat exchanger 410.

Some embodiments of the present disclosure can take the form of a first semiconductor device. The semiconductor device includes a backside power distribution (BSPDN), a high thermal conductivity dielectric layer, a heat sink, and a heat transfer pillar. The heat transfer pillar is connected to the high thermal conductivity dielectric layer and extends to the heat sink. This may allow for efficient heat transfer in a semiconductor device that utilizes a BSPDN.

In some examples of the first semiconductor device, the semiconductor device further includes a front end of line (FEOL) region on the BSPDN, and a middle of line/front end of line (MOL/BEOL) region on the FEOL. For a semiconductor device including a BSPDN, the high thermal conductivity dielectric layer may allow for efficient heat transfer.

In some examples of the first semiconductor device, the high thermal conductivity dielectric layer is formed in the FEOL region, and the heat transfer pillar extends from the FEOL region to the heat sink. This may allow for design flexibility in determining a location for the high thermal conductivity dielectric layer, while still achieving efficient transfer.

In some examples of the first semiconductor device, the high thermal conductivity dielectric layer is formed at an interface between the FEOL region and the MOL/BEOL, and the heat transfer pillar extends from the FEOL region to the heat sink. This may allow for design flexibility in determining a location for the high thermal conductivity dielectric layer, while still achieving efficient transfer.

In some examples of the first semiconductor device, the high thermal conductivity dielectric layer is formed in the MOL/BEOL region, and the heat transfer pillar extends from the MOL/BEOL region to the heat sink. This may allow for design flexibility in determining a location for the high thermal conductivity dielectric layer, while still achieving efficient transfer.

In some examples of the first semiconductor device, the high thermal conductivity dielectric layer is formed at an interface between the BSPDN and the FEOL region, and the heat transfer pillar extends from the BSPDN to the heat sink. This may allow for design flexibility in determining a location for the high thermal conductivity dielectric layer, while still achieving efficient transfer.

In some examples of the first semiconductor device, the high thermal conductivity dielectric layer is formed in the BSPDN, and the heat transfer pillar extends from the BSPDN to the heat sink. This may allow for design flexibility in determining a location for the high thermal conductivity dielectric layer, while still achieving efficient transfer.

In some examples of the first semiconductor device, the high thermal conductivity dielectric layer comprises hexagonal boron nitride (hBN). For a semiconductor device including a BSPDN, the high thermal conductivity dielectric layer including hBN may allow for efficient heat transfer.

In some examples of the first semiconductor device, the first semiconductor device further includes a first nanosheet field effect transistor (FET) including a first nanosheet stack, a first epitaxial layer in contact with the first nanosheet stack, and a first metal contact on a top side of the first epitaxial layer, and a second nanosheet field effect transistor (FET) including a second nanosheet stack, a second epitaxial layer in contact with the second nanosheet stack, and a second metal contact on a bottom side of the second epitaxial layer.

In some examples of the first semiconductor device, the first semiconductor device further includes a placeholder layer comprising SiGe formed adjacent to the first epitaxial layer. The placeholder layer allows for forming a backside metal contact for connection to a nanosheet field effect transistor.

In some examples of the first semiconductor device, the high thermal conductivity dielectric layer is formed in contact with the placeholder layer. The placeholder layer allows for forming a backside metal contact for connection to a nanosheet field effect transistor.

Some embodiments of the present disclosure can take the form of an electronic device. The electronic device includes a semiconductor device that includes a backside power distribution (BSPDN), a high thermal conductivity dielectric layer, a heat sink, and a heat transfer pillar. The heat transfer pillar is connected to the high thermal conductivity dielectric layer and extends to the heat sink. This may allow for efficient heat transfer in a semiconductor device that utilizes a BSPDN.

In some examples of the electronic device, the semiconductor device further includes a front end of line (FEOL) region on the BSPDN, and a middle of line/front end of line (MOL/BEOL) region on the FEOL. For a semiconductor device including a BSPDN, the high thermal conductivity dielectric layer may allow for efficient heat transfer.

In some examples of the electronic device, the high thermal conductivity dielectric layer is formed in the FEOL region, and the heat transfer pillar extends from the FEOL region to the heat sink. This may allow for design flexibility in determining a location for the high thermal conductivity dielectric layer, while still achieving efficient transfer.

In some examples of the electronic device, the high thermal conductivity dielectric layer is formed at an interface between the FEOL region and the MOL/BEOL, and the heat transfer pillar extends from the FEOL region to the heat sink. This may allow for design flexibility in determining a location for the high thermal conductivity dielectric layer, while still achieving efficient transfer.

In some examples of the electronic device, the high thermal conductivity dielectric layer is formed in the MOL/BEOL region, and the heat transfer pillar extends from the MOL/BEOL region to the heat sink. This may allow for design flexibility in determining a location for the high thermal conductivity dielectric layer, while still achieving efficient transfer.

In some examples of the electronic device, the high thermal conductivity dielectric layer is formed at an interface between the BSPDN and the FEOL region, and the heat transfer pillar extends from the BSPDN to the heat sink. This may allow for design flexibility in determining a location for the high thermal conductivity dielectric layer, while still achieving efficient transfer.

In some examples of the electronic device, the high thermal conductivity dielectric layer is formed in the BSPDN, and the heat transfer pillar extends from the BSPDN to the heat sink. This may allow for design flexibility in determining a location for the high thermal conductivity dielectric layer, while still achieving efficient transfer.

In some examples of the electronic device, the high thermal conductivity dielectric layer comprises hexagonal boron nitride (hBN). For a semiconductor device including a BSPDN, the high thermal conductivity dielectric layer including hBN may allow for efficient heat transfer.

In some examples of the electronic device, the first semiconductor device further includes a first nanosheet field effect transistor (FET) including a first nanosheet stack, a first epitaxial layer in contact with the first nanosheet stack, and a first metal contact on a top side of the first epitaxial layer, and a second nanosheet field effect transistor (FET) including a second nanosheet stack, a second epitaxial layer in contact with the second nanosheet stack, and a second metal contact on a bottom side of the second epitaxial layer.

In some examples of the electronic device, the first semiconductor device further includes a placeholder layer comprising SiGe formed adjacent to the first epitaxial layer. The placeholder layer allows for forming a backside metal contact for connection to a nanosheet field effect transistor.

In some examples of the electronic device, the high thermal conductivity dielectric layer is formed in contact with the placeholder layer. The placeholder layer allows for forming a backside metal contact for connection to a nanosheet field effect transistor.

Some embodiments of the present disclosure can take the form of a second semiconductor device. The second semiconductor device includes a backside power distribution (BSPDN), a front end of line (FEOL) region on the BSPDN, a middle of line/back end of line (MOL/BEOL) region on the FEOL, a heat sink on the MOL/BEOL region, a high thermal conductivity dielectric layer, a heat transfer pillar connected to the high thermal conductivity dielectric layer and extending to the heat sink. This may allow for efficient heat transfer in a semiconductor device that utilizes a BSPDN.

In some examples of the second semiconductor device, the high thermal conductivity dielectric layer comprises hexagonal boron nitride (hBN). This may allow for efficient heat transfer in a semiconductor device that utilizes a BSPDN.

In some examples of the second semiconductor device, the high thermal conductivity dielectric layer is formed in the FEOL region, and the heat transfer pillar extends from the FEOL region to the heat sink. This may allow for design flexibility in determining a location for the high thermal conductivity dielectric layer, while still achieving efficient transfer.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a backside power distribution network (BSPDN);
a high thermal conductivity dielectric layer;
a heat sink; and
a heat transfer pillar connected to the high thermal conductivity dielectric layer and extending to the heat sink.

2. The semiconductor device of claim 1, further comprising a front end of line (FEOL) region on the BSPDN and a middle of line/back end of line (MOL/BEOL) region on the FEOL.

3. The semiconductor device of claim 2, wherein the high thermal conductivity dielectric layer is formed in the FEOL region, and the heat transfer pillar extends from the FEOL region to the heat sink.

4. The semiconductor device of claim 2, wherein the high thermal conductivity dielectric layer is formed at an interface between the FEOL region and the MOL/BEOL, and the heat transfer pillar extends from the FEOL region to the heat sink.

5. The semiconductor device of claim 2, wherein the high thermal conductivity dielectric layer is formed in the MOL/BEOL region, and the heat transfer pillar extends from the MOL/BEOL region to the heat sink.

6. The semiconductor device of claim 2, wherein the high thermal conductivity dielectric layer is formed at an interface between the BSPDN and the FEOL region, and the heat transfer pillar extends from the BSPDN to the heat sink.

7. The semiconductor device of claim 2, wherein the high thermal conductivity dielectric layer is formed in the BSPDN, and the heat transfer pillar extends from the BSPDN to the heat sink.

8. The semiconductor device of claim 1, wherein the high thermal conductivity dielectric layer comprises hexagonal boron nitride (hBN).

9. The semiconductor device of claim 1, further comprising:
a first nanosheet field effect transistor (FET) including a first nanosheet stack, a first epitaxial layer in contact with the first nanosheet stack, and a first metal contact on a top side of the first epitaxial layer; and
a second nanosheet field effect transistor (FET) including a second nanosheet stack, a second epitaxial layer in contact with the second nanosheet stack, and a second metal contact on a bottom side of the second epitaxial layer.

10. The semiconductor device of claim 9, further comprising a placeholder layer comprising SiGe formed adjacent to the first epitaxial layer.

11. The semiconductor device of claim 10, wherein the high thermal conductivity dielectric layer is formed in contact with the placeholder layer.

12. An electronic device comprising:
a semiconductor device including
a backside power distribution network (BSPDN);
a high thermal conductivity dielectric layer;
a heat sink; and
a heat transfer pillar connected to the high thermal conductivity dielectric layer and extending to the heat sink.

13. The electronic device of claim 12, further comprising a front end of line (FEOL) region on the BSPDN and a middle of line/back end of line (MOL/BEOL) region on the FEOL.

14. The electronic device of claim 13, wherein the high thermal conductivity dielectric layer is formed in the FEOL region, and the heat transfer pillar extends from the FEOL region to the heat sink.

15. The electronic device of claim 13, wherein the high thermal conductivity dielectric layer is formed at an interface between the FEOL region and the MOL/BEOL, and the heat transfer pillar extends from the FEOL region to the heat sink.

16. The electronic device of claim 13, wherein the high thermal conductivity dielectric layer is formed in the MOL/BEOL region, and the heat transfer pillar extends from the MOL/BEOL region to the heat sink.

17. The electronic device of claim 13, wherein the high thermal conductivity dielectric layer is formed at an interface between the BSPDN and the FEOL region, and the heat transfer pillar extends from the BSPDN to the heat sink.

18. The electronic device of claim 13, wherein the high thermal conductivity dielectric layer is formed in the BSPDN, and the heat transfer pillar extends from the BSPDN to the heat sink.

19. The electronic device of claim 12, wherein the high thermal conductivity dielectric layer comprises hexagonal boron nitride (hBN).

20. The electronic device of claim 12, further comprising:
a first nanosheet field effect transistor (FET) including a first nanosheet stack, a first epitaxial layer in contact with the first nanosheet stack, and a first metal contact on a top side of the first epitaxial layer; and
a second nanosheet field effect transistor (FET) including a second nanosheet stack, a second epitaxial layer in contact with the second nanosheet stack, and a second metal contact on a bottom side of the second epitaxial layer.

21. The electronic device of claim 20, further comprising a placeholder layer comprising SiGe formed adjacent to the first epitaxial layer.

22. The electronic device of claim 21, wherein the high thermal conductivity dielectric layer is formed in contact with the placeholder layer.

23. A semiconductor device comprising:
a backside power distribution network (BSPDN);
a front end of line (FEOL) region on the BSPDN;
a middle of line/back end of line (MOL/BEOL) region on the FEOL;
a heat sink on the MOL/BEOL region;
a high thermal conductivity dielectric layer;
a heat transfer pillar connected to the high thermal conductivity dielectric layer and extending to the heat sink.

24. The semiconductor device of claim 12, wherein the high thermal conductivity dielectric layer comprises hexagonal boron nitride (hBN).

25. The semiconductor device of claim 12, wherein the high thermal conductivity dielectric layer is formed in the FEOL region, and the heat transfer pillar extends from the FEOL region to the heat sink.
